(19) United States
(12) Patent Application Publication
(10) Pub. No.: US 2010/0126904 A1
(43) Pub. Date: May 27, 2010

(54) Thin-plate container

(76) Inventors: Kung-Hao Cheng, Shulin city (TW); Chang-Cheng Chen, Shulin City (TW)

Correspondence Address: SINORICA, LLC, 2275 Research Blvd., Suite 500, ROCKVILLE, MD, 20850, US

(21) Appl. No.: 12/329,668

(22) Filed: Dec. 8, 2008

(30) Foreign Application Priority Data
Nov. 21, 2008 (TW) 097145027

(51) Int. Cl. H01L 21/673

(52) U.S. Cl. 206/710; 414/217.1

(57) ABSTRACT

A thin-plate container comprises a container body with an opening and an interior area and being pivotally connected to at least a pair of swing hooks near its opening; a container door for closing the opening of the container body; and a latch component disposed in the container door, which is movable in a to-and-fro direction between a first position and a second position when the container door closes the opening of the container body, wherein in the first position, the latch component is contained in the container door, and in the second position, the latch component extends beyond the container door and is in contact with the pair of swing hooks of the container body for making the container door to move in a sealing direction by using the swing hooks to achieve a sealed status between the container door and the container body.

### BACKGROUND OF THE INVENTION

1. Field of the Invention

The present field of the invention is related to a thin-plate container, and more particularly, to a thin-plate container with high air tightness ability.

2. Description of the Prior Art

Currently in semiconductor fabrication plants, most storage devices of wafer and photomask use a standardized mechanical interface (SMIF) proposed by Hewlett-Packard Co., which has been disclosed in U.S. Pat. No. 4,532,970 and U.S. Pat. No. 4,534,389. The purpose of SMIF system is to ensure that during the transporting and storing process, gas surrounding wafer and reticle is basically static in relation to the wafer and reticle, and that particles in the ambient environment will not enter the space surrounding the wafer and reticle.

Therefore a transport container used in SMIF system needs to be equipped with high air tightness ability to prevent gas or particles of the exterior environment from entering the transport container. Referring to FIG. 1A and FIG. 1B, which are views of container body and container door of transport container of the prior art achieving status of air tightness. The transport container includes a container body 10 and a container door 20 with an outer surface 21 and an inner surface 22, the inner surface 22 of the container door 20 being used for closing an opening 14 of the container body 10. And in the interior of container door 20, i.e. between the outer surface 21 and the inner surface 22, is disposed with a latch component that includes a cam 200 and a pair of moving bars 300 (only one moving bar is shown in the Figure), one end of the moving bars 300 being disposed with a roller 301 that is able to roll on top of the cam 200. Therefore, when a latch hole 21H of the outer surface 21 of the container door 20 is used to roll the cam 200, the cam 200 will drive the moving bars 300 to extend horizontally out of the container door 20 (as shown in FIG. 1A). And with the rolling of the cam 200 continues, the roller 301 of the moving bars 300 rolls onto a platform 201 on the cam 200 and causes the moving bars 300 to deviate in the direction perpendicular to its original direction of movement and further presses the lower rim 10L of the hole on container body 10. Finally, the whole container door 20 is raised up toward the interior of the container body 10 for some distance, and a seal element 26 on the container door 20 is caused to contact a protruding body 17 on the container body to achieve air tightness (FIG. 1B).

Although air tightness can be achieved in the aforementioned transport container, yet the force raising up the container door 20 toward the interior of the container body 10 is not enough, which easily causes gap to exist between the protruding body 17 and the seal element 26; moreover, the structure of latch component is relatively more complex and it is easier for dust particles to be generated when the roller 301 is used to roll on the cam 200, which poses an apparent threat to object in the interior of the container.

### SUMMARY OF THE INVENTION

In view of the aforementioned problems of the prior art that the effect of air tightness of transport container is not good enough and that the application of roller easily causes dust particles, one objective of the present invention is to provide a transport container with good air tightness effect, wherein the force for raising up the container door and the distance raised are both sufficient for achieving good air tightness effect between the container body and the container door.

Another objective of the present invention is to provide a transport container with good air tightness effect, wherein the design of roller is not applied in the latch component of the transport container of the present invention to reduce dust particles generated when the roller rolls on the platform of cam each time the container door is opened or closed.

Still another objective of the present invention is to provide a transport container with good air tightness effect, in which a latch component with simple design is applied, wherein the moving bars are only made to extend horizontally out of the container door and do not need to move in two different directions.

According to above objectives, the present invention discloses a thin-plate sealed container, comprising: a container body with a top surface and four side surfaces neighboring to the top surface, the top surface and the side surfaces forming an interior area and an opening, wherein in the interior area, two opposite side surfaces among the four side surfaces are respectively pivotally connected to a swing hook; a container door with an inner surface for closing the opening of the container body; a plurality of supporting pillars disposed on the inner surface of the container door for supporting a thin plate; a seal element disposed around the four edges of the inner surface of the container door; and a latch component disposed in the container door that drives a pair of moving bars to move in a to-and-fro direction between a first position and a second position by using a cam when the inner surface of the container door closes the opening of the container body, wherein in the first position, the moving bars are contained in the container door, and in the second position, the moving bars extend beyond the container door and are in contact with the pair of swing hooks of the container body for making the container door to move in a sealing direction by using the swing hooks to achieve a sealed status between the container door and the container body with the seal element.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A and FIG. 1B are views of container body and container door of transport container of the prior art achieving status of air tightness;

FIG. 2 is a view of thin-plate container of the present invention;

FIG. 3 is a view of interior area of container body of the container of the present invention;

FIG. 4 is a view of swing hook of the container of the present invention;

FIG. 5A is a view of container door of the container of the present invention when being unfastened;

FIG. 5B is a view of container door of the container of the present invention when being fastened;

FIG. 6 is a view of side surface of container door of the container of the present invention;

FIG. 7 is a view of container door of the container of the present invention being raised up by the swing hook;

FIG. 8A and FIG. 8B are views of button hook of swing hook before and after hooking and raising the container door;

FIG. 9 is a view of container door of the container of the present invention placed with thin plate; and

FIG. 10 is a view of container door of the container of the present invention without thin plate placed.

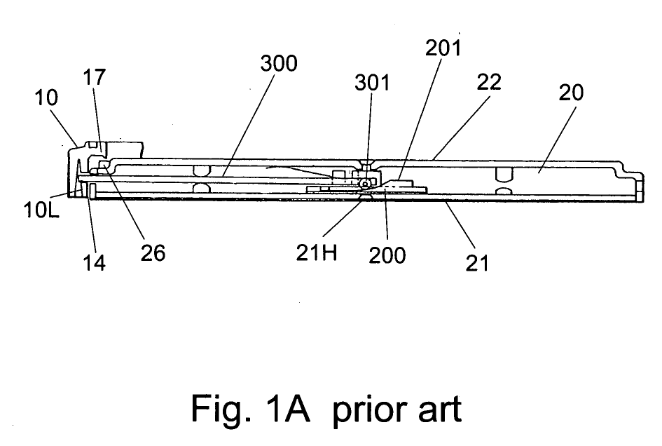

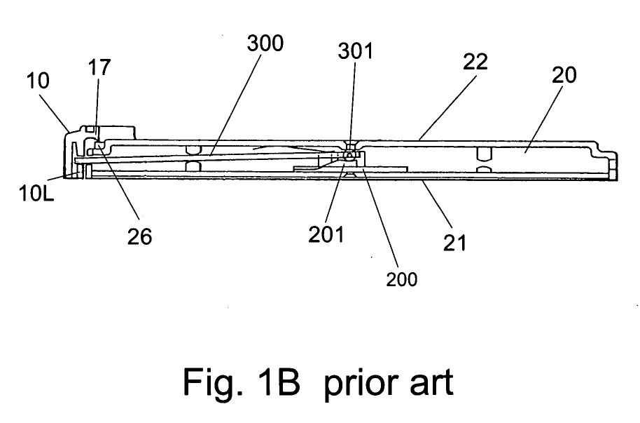

### DESCRIPTION OF THE PREFERRED EMBODIMENT

In order to disclose the skills applied in, the objectives of, and the effects achieved by the present invention in a more complete and clearer manner, preferred embodiments are herein described below in detail with related drawings disclosed for reference.

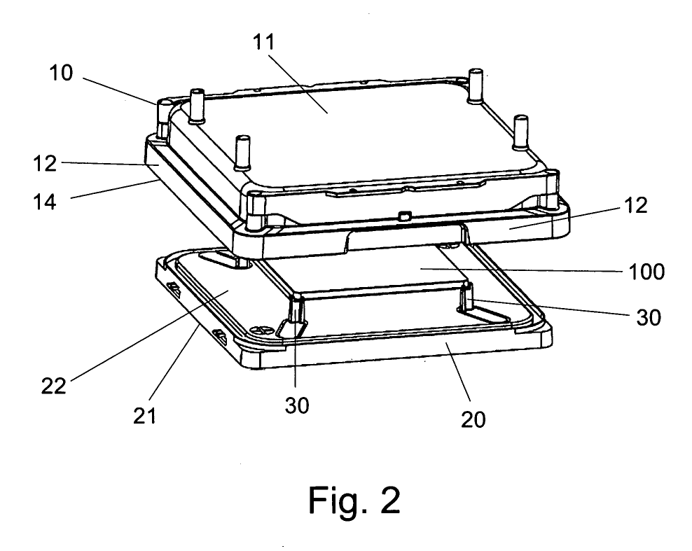

First, referring to FIG. 2, which is a view of thin-plate container of the present invention. The thin-plate container includes a container body 10 and a container door 20, the container body 10 having a top surface 11 and four side surfaces 12 neighboring to the top surface 11, the aforementioned top surface 11 and the four side surfaces 12 forming an interior area (not shown in Figure) and an opening 14; the container door 20 having an outer surface 21 and an inner surface 22, wherein the inner surface 22 is used for closing the opening 14 of the container body 10 and is respectively disposed with a supporting pillar 30 in each of its four corners for supporting a thin plate 100, the thin plate 100 being a reticle or a semiconductor substrate, and the outer surface 21 of the container door 20 is disposed with a latch hole (not shown in Figure) for fastening or unfastening the container door 10 and the container body 20 with the rotation of this latch hole.

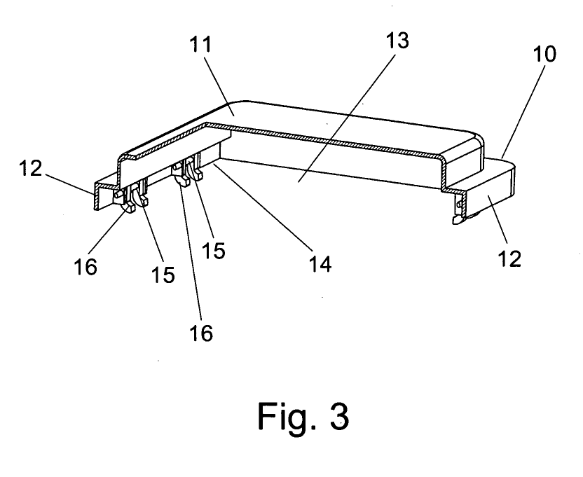

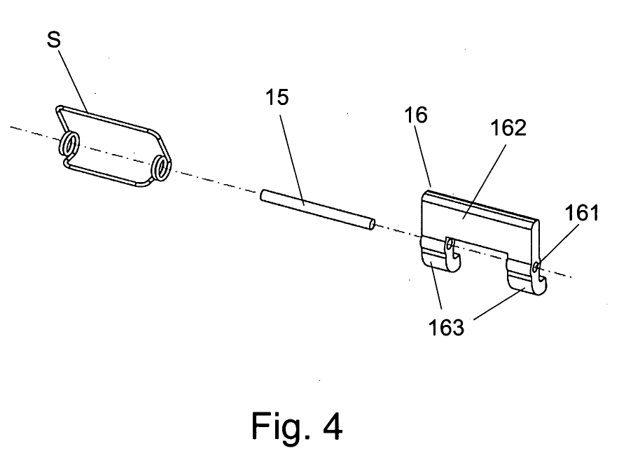

Then, referring to FIG. 3, which is a view of the interior area 13 of the container body 10 of the aforementioned container. As can be observed in the Figure, four pivot levers 15 (only two pivot levers are shown in the Figure) are disposed near the opening 14 in the interior area 13 of the container body 10, wherein two pivot levers 15 are disposed on one side surface 12 among four side surfaces 12, and the rest two pivot levers 15 are disposed on the side surface 12 opposite to the aforementioned side surface 12. Each of the aforementioned pivot levers 15 is pivotally connected to a swing hook 16, as shown in FIG. 4, and each swing hook 16 includes a pivot hole 161, a top body 162 extends on top of the pivot hole 161, and at least a button hook 163 extends below and outside the pivot hole 161; the swing hook 16 is pivotally connected to the pivot lever 15 of the container body 10 with its pivot hole 161, and the swing hook 16 and the side surface 12 are kept in parallel with a swing device S.

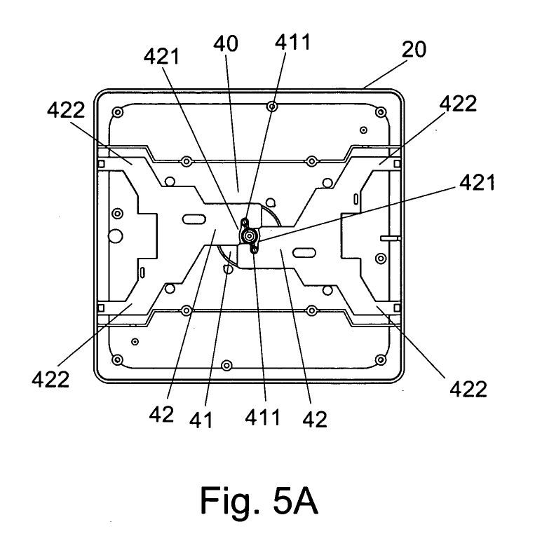

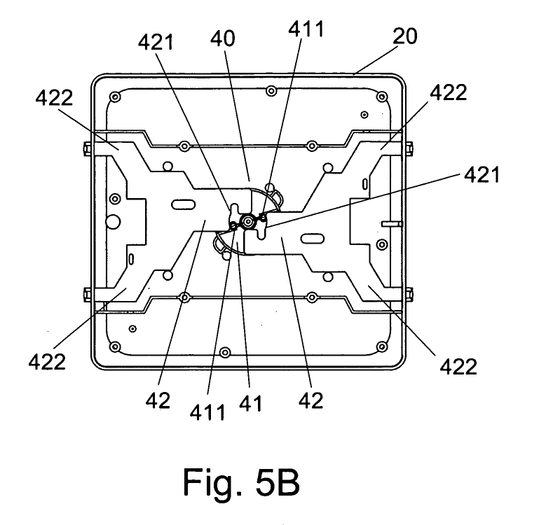

And as shown in FIG. 5A and FIG. 5B, which are views of the container door 20 of the aforementioned container when being unfastened and fastened; in FIG. 5A and FIG. 5B, the inner surface 22 of the container door 20 is already removed. As described above, the container door 20 of the container of the present invention includes outer surface 21 and inner surface 22, wherein in the container door 20 (i.e. between the outer surface 21 and the inner surface 22) is disposed with a latch component 40 that includes a cam 41 and a pair of moving bars 42, the cam 41 having a hole (not shown in Figure) for connecting to the latch hole on the outer surface 21. In addition, the cam 41 is disposed with a pair of first guide structures, which is protruding portion 411 or protruding structure extending outward from the center point of the cam 41; and on the end of each moving bar 42 near the cam 41 is disposed with a second guide structure, the structure and shape of which coincide with those of the first guide structures, for example, the second guide structure is designed as curved notch 421 that coincide with the protruding portion 411, and on the other end of each moving bar 42 far from the cam 41 are formed with two latch arms 422, the positions of which are opposite to the swing hooks 16 in the interior area 13 of the container body 10. And since the shape of the first guide structure and that of the second guide structure coincide with each other, the aforementioned first guide structure and the second guide structure can be driven into the status of engagement or disengagement by rotating the cam 41. In the status of engagement (shown in FIG. 5A), the first guide structures on the cam 41 coincide with the second guide structures on the moving bars 42, and meantime, the latch arms 422 of moving bars 42 are contained in the container door 20; in the status of disengagement (shown in FIG. 5B), the first guide structures of the cam 41 escape from the second guide structures on the moving bars 42 and push the latch arms 422 of the moving bars 42 outward for the latch arms 422 of the moving bars 42 to extend out of the container door 20 to contact swing hooks 16. Apparently, the main function of the latch component 40 is to make the moving bars 42 and its latch arms 422 to move in a to-and-fro direction between the aforementioned two positions either for the moving bars 42 to extend out of the container door 20 to fasten the container body 10 or for the moving bars 42 to retract into the container door 20 to unfasten the container body 10. And the material of the aforementioned cam 41 or moving bars 42 of the latch component 40 can be metal or polymer plastic or other materials, which is not limited in the present invention. And the structure of latch component 40 is not limited to that as described above either.

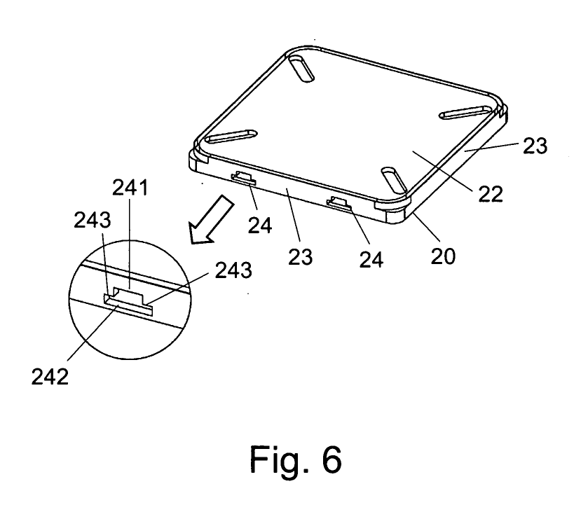

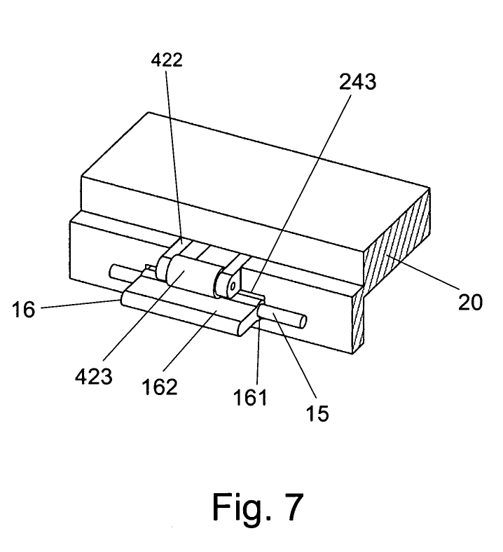

Moreover, as shown in FIG. 6, there are four side surfaces 23 neighboring to the inner surface 22 of the container door 20, and each of the two opposite side surfaces 23 among the four side surfaces 23 respectively includes two windows 24, wherein each window 24 includes a small window 241 of upper portion and a large window 242 of lower portion. The small window 241 of upper portion allows the latch arm 422 of the moving bars 42 in the container door 20 to extend out of it to contact top body 162 of the swing hook 16, and the large window 242 of lower portion allows the button hook 163 of the swing hook 16 to pass through it to hook the overlapping part 243 between the small window 241 and the large window 242. As shown in FIG. 7 (only structures such as the pivot lever 15 and swing hook 16 in the container body 10 and the container door 20 are left in this Figure), after the latch arm 422 of the moving bar 42 extend out of the container door 20, the latch arm 422 contacts or presses the top body 162 of the swing hook 16 to make the swing hook 16 rotate with the pivot hole 161 or pivot lever 15 as center from being parallel to the side surface 12 to being perpendicular to the side surface 12; meantime, the button hook 163 of swing hook 16 hooks the overlapping part 243 between the small window 241 and the large window 242 and allows the container door 20 to be raised up a distance.

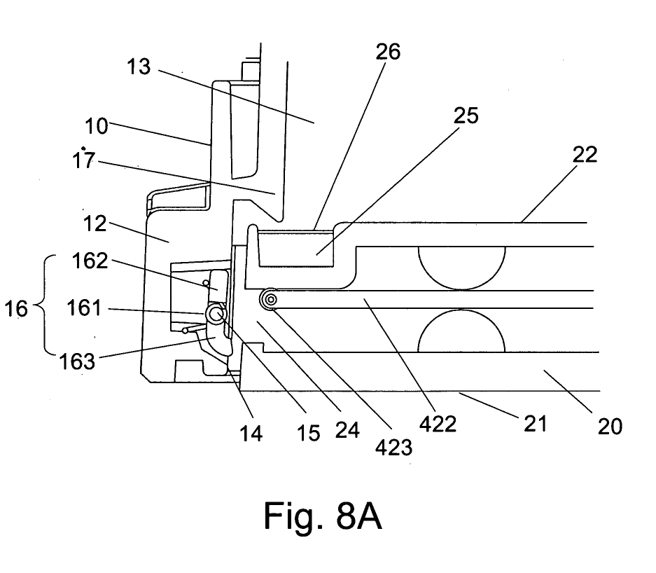

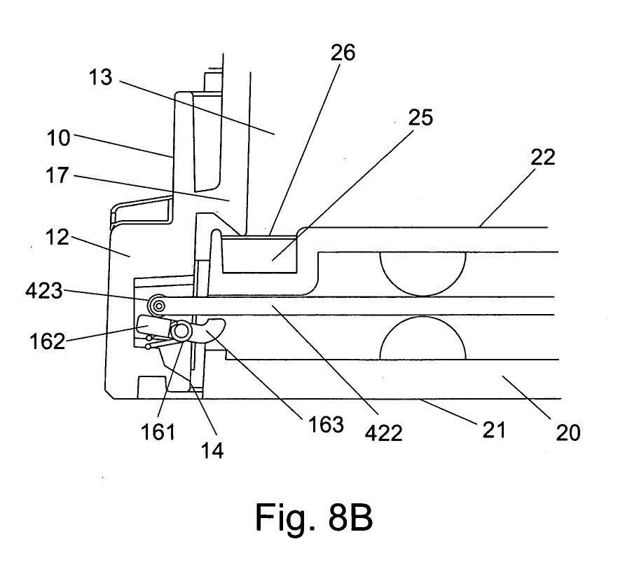

Then, referring to FIG. 8A and FIG. 8B, which are views of the button hook 163 of the swing hook 16 before and after hooking and raising the container door 20. As can be observed from the Figure, around the four edges of the inner surface 22 of the container door 20 is disposed a groove 25, in which is a seal element 26, and on the container body 10 opposite to the position of the seal element 26 includes a protruding body 17. Therefore, when the latch arms 422 of the moving bars 42 in the container door 20 extend out of the container door 20 and contact the top body 162, the button hooks 163 of the swing hooks 16 raise up the container door 20 and cause close contact between the protruding body 17 and the seal element 26 and air tightness between the container body 10 and the container door 20. And the aforementioned up-raising direction or sealing direction and the to-and-fro direction of the latch arms 422 of the moving bars 42 are in a right angle. And the aforementioned seal element 26 used can be a rubber band or a seal ring, the material of which can be rubber or polymer plastic or other materials. In addition, to reduce the contact area between the latch arms 422 and the top body 162 and to reduce the dust particles generated, the free end of each latch arm 422 can include a roller 423 and the surface of roller 423 is coated with a wear-resistant material, polyetheretherketone, PEEK, for example.

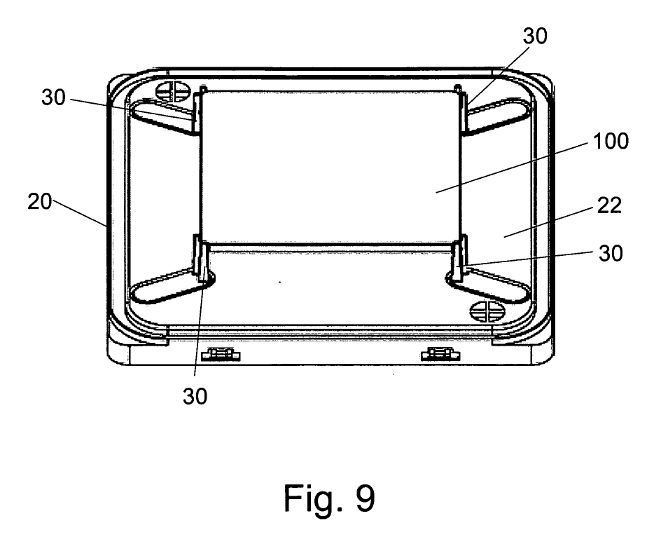

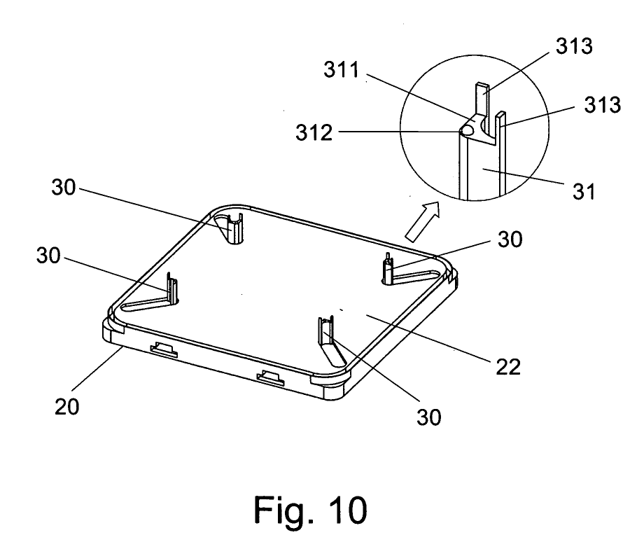

Then, referring to FIG. 9, which is a view of container door of the container of the present invention placed with thin plate. And FIG. 10 is a view of the aforementioned container door with the thin plate removed and a plurality of supporting pillars retained. As shown in the figures, the four supporting pillars 30 are located in the four corners of the inner surface 22 of the container door 20, wherein each supporting pillar 30 includes a base 31 with the bottom end of it fixed on the inner surface 22 of the container door 20 and the other end of it forming a top surface 311, a protruding point 312 being disposed on the top surface 311 for supporting the thin plate 100. And on the edge of the top surface 311 is disposed with at least a protruding block 313 extending upward to prevent the thin plate 100 from sliding off the supporting pillars 30. And under normal situation in which thin plate 100 is placed in the container, the aforementioned thin plate 100 is only supported on top of the protruding point 312 without contacting the protruding block 313; the supporting pillars 30 can be used together with locating piece (not shown in Figure) in the interior area 13 of the container body 10 for fixing the thin plate 100 between the locating piece and the supporting pillars 30. And when the container of the present invention is under an impact force, for example, when the container drops down from the working platform, the protruding block 313 can exert its function by blocking or preventing the thin plate 100 from sliding off the supporting pillars 30.

While the invention has been described by way of examples and in terms of the preferred embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A thin-plate container, comprising:
a container body, with an opening and an interior area, being pivotally connected to at least a pair of swing hooks near said opening;
a container door, with an inner surface for closing said opening of said container body;
a plurality of supporting pillars, disposed at four corners of said inner surface of said container door for supporting a thin plate; and
a latch component, disposed in said container door, moving in a to-and-fro direction between a first position and a second position when said inner surface of said container door closes said opening of said container body, in said first position said latch component being contained in said container door, and in said second position, said latch component extending out of said container door and contacting said plurality of swing hooks of said container body and moving said container door toward a sealing direction by using said plurality of swing hooks for achieving status of sealedness between said container door and said container body.

2. The container according to claim 1, wherein around four edges of said inner surface of said container door is disposed with a seal element.

3. The container according to claim 2, wherein a protruding body is disposed on said container body opposite to position of said seal element, said protruding body pressing said seal element when said plurality of swing hooks driving said container door to move in said sealing direction for achieving status of sealedness between said container door and said container body.

4. The container according to claim 1, wherein neighboring to said inner surface of said container door are four side surfaces, each of two opposite side surfaces among said four side surfaces being respectively disposed with at least a window for allowing said latch component to extend out of said container door.

5. The container according to claim 1, wherein said swing hook further includes a pivot hole, said pivot hole being disposed in a pivot lever near said opening of said container body.

6. The container according to claim 5, wherein a top body extends upward from said pivot hole of said swing hook and at least a button hook extends below and outside said pivot hole, said top body provided for being contacted by said latch component and rotating with said pivot hole as center for driving said button hook to hook said container door and to drive said container door to move in said sealing direction.

7. The container according to claim 1, wherein said latch component includes a cam and a pair of moving bars, said cam being disposed with a pair of first guide structures and one end of said pair of moving bars being disposed with a second guide structure, said first guide structures and said second guide structure being driven into status of engagement or disengagement by the rotation of said cam.

8. The container according to claim 7, wherein when said first guide structures and said second guide structure are in status of engagement, said pair of moving bars are contained in said container door.

9. The container according to claim 7, wherein when said first guide structures and said second guide structure are in status of disengagement, said pair of moving bars extend out of said container door and contact said plurality of swing hooks of said container body.

10. A thin-plate sealed container, comprising:
a container body, with a top surface and four side surfaces neighboring to said top surface, said top surface and said side surfaces forming an interior area and an opening, wherein in said interior area each of two opposite side surfaces among said four side surfaces is respectively pivotally connected to a swing hook;
a container door, with an inner surface for closing said opening of said container body;
a plurality of supporting pillars, disposed at four corners of said inner surface of said container door for supporting a thin plate;
a seal element, disposed around four edges of said inner surface of said container door; and
a latch component, disposed in said container door, that includes a cam and a pair of moving bars, a pair of moving bars of latch component are movable in a to-and-fro direction between a first position and a second position by the rotation of said cam when said inner surface of said container door closes said opening of said container body, in said first position said pair of moving bars being contained in said container door, and in said second position, said pair of moving bars extending out of said container door and contacting said plurality of swing hooks of said container body and moving said container door toward a sealing direction by using said plurality of swing hooks for using said seal element to achieve status of sealedness between said container door and said container body.

11. The container according to claim 10, wherein said to-and-fro direction is perpendicular to said sealing direction.

12. The container according to claim 10, wherein a protruding body is disposed on said container body opposite to position of said seal element, said protruding body pressing said seal element when said plurality of swing hooks driving said container door to move in said sealing direction for achieving status of sealedness between said container door and said container body.

13. The container according to claim 10, wherein neighboring to said inner surface of said container door are four side surfaces, each of two opposite side surfaces among said four side surfaces being respectively disposed with at least a window for allowing said pair of moving bars to extend out of said container door.

14. The container according to claim 10, wherein each of said two opposite side surfaces in said interior area of said container body includes a pivot lever for being pivotally disposed with a pivot hole of said swing hook.

15. The container according to claim 14, wherein a top body extends upward from said pivot hole of said swing hook and at least a button hook extends below and outside said pivot hole, said top body provided for being contacted by said pair of moving bars and rotating with said pivot hole as center for driving said button hook to hook said container door and to drive said container door to move in said sealing direction.

16. The container according to claim 10, wherein said cam is disposed with a pair of first guide structures and one end of said pair of moving bars is disposed with a second guide structure, said first guide structures and said second guide structure being driven into status of engagement or disengagement by the rotation of said cam.

17. The container according to claim 16, wherein when said first guide structures and said second guide structure are in status of engagement, said pair of moving bars are contained in said container door.

18. The container according to claim 16, wherein when said first guide structures and said second guide structure are in status of disengagement, said pair of moving bars extend out of said container door and contact said plurality of swing hooks of said container body.

19. The container according to claim 10, wherein each of said plurality of supporting pillars comprises:
a base, fixed on said inner surface of said container door, said base including a top surface and said top surface being disposed with a protruding point, said protruding point being used for supporting said thin plate; and
a protruding block, located on edge of said top surface of said base, said protruding block preventing said thin plate from sliding off said supporting pillar.

20. The container according to claim 10, wherein said thin plate is a reticle.
